(19) United States
(12) Patent Application Publication
(10) Pub. No.: US 2025/0141438 A1
(43) Pub. Date: May 1, 2025

(54) EVALUATING PERFORMANCE OF A DROOP MITIGATION SCHEME

(71) Applicant: Arm Limited, Cambridge (GB)

(72) Inventors: Amit Chhabra, Noida (IN); Rainer Herberholz, Great Abington (GB)

(73) Assignee: Arm Limited, Cambridge (GB)

(21) Appl. No.: 18/926,235

(22) Filed: Oct. 24, 2024

(30) Foreign Application Priority Data
Oct. 27, 2023 (IN) 202311073299
Mar. 20, 2024 (GB) 2403978.6

(51) Int. Cl. H03K 5/01; G06F 1/04; H03K 5/00

(52) U.S. Cl. CPC H03K 5/01; G06F 1/04; H03K 2005/00019

(57) ABSTRACT

The present techniques relate to droop mitigation scheme and there is disclosed a method of evaluating the performance of a droop mitigation scheme, wherein the method is carried out at a circuit, the method comprising: receiving a clock output signal, wherein the droop mitigation scheme has been used to generate the clock output signal; and analysing the clock output signal to generate an output, wherein the output provides an indication of the performance of the droop mitigation scheme.

### TECHNICAL FIELD

The present techniques relate to droop mitigation schemes. In particular, the present techniques relate to evaluating the performance of a droop mitigation scheme used to generate a clock output signal.

### BACKGROUND OF THE DISCLOSURE

Some computer circuits (e.g. a central processor unit (CPU) or graphics processor unit (GPU)) may experience performance issues. For example, a CPU can generate voltage droops due to large changes in current required from a power delivery network (PDN).

There is a need for mitigation action to address such performance issues.

### SUMMARY OF THE DISCLOSURE

The present techniques relate to addressing or mitigating such performance issues or improving known mitigation techniques.

In a first approach there is provided a method of evaluating the performance of a droop mitigation scheme, wherein the method is carried out at a circuit, the method comprising: receiving a clock output signal, wherein the droop mitigation scheme has been used to generate the clock output signal; and analysing the clock output signal to generate an output, wherein the output provides an indication of the performance of the droop mitigation scheme.

The method may further comprise: using the droop mitigation scheme to generate the clock output signal, wherein the droop mitigation scheme may comprise adjusting the frequency of the clock output signal in response to a droop event.

Using a droop mitigation scheme to generate the clock output signal may comprise: receiving a plurality of clock input signals, the plurality of clock input signals comprising a nominal clock signal and a fallback clock signal; providing, for at least a first time period, the nominal clock signal as the clock output signal; and providing, for at least a second time period, the fallback clock signal or no signal as the clock output signal. The method may further comprise: monitoring the voltage for a voltage droop event.

Using a droop mitigation scheme to generate a clock output signal may further comprise: initially providing the nominal clock signal as the clock output signal; responsive to detecting a voltage droop event, providing the fallback clock signal or no signal as the clock output signal.

The nominal clock signal and the fallback clock signal may have different frequencies.

The method may further comprise: evaluating the performance of the droop mitigation scheme, based on at least the output, wherein evaluating, based on at least the output, the performance of the droop mitigation scheme may comprise: comparing an output value of the output with one or more thresholds. Evaluating, based on the output, the performance of the droop mitigation scheme may comprise: in response to determining that the output is below a threshold, providing a droop performance indication signal or adjusting the droop mitigation scheme.

The circuit may comprise a clock circuit comprising a plurality of clock sources and a clock mux, wherein the plurality of clock sources may comprise a nominal clock source and a fallback clock source.

The circuit may comprise a droop detector configured to detect droop in the nominal clock signal.

The circuit may comprise a droop mitigation state machine configured to provide a clock selection signal to the clock circuit, in response to detection of droop in the nominal clock signal by the droop detector.

The circuit may comprise a delay monitor configured to generate the output, where the delay monitor may comprise at least one delay line and an encoder.

In a further approach there is provided a circuit for evaluating the performance of a droop mitigation scheme, the circuit comprising a delay monitor configured to: receive a clock output signal, wherein the droop mitigation scheme has been used to generate the clock output signal; analyse the clock output signal to generate an output, wherein the output provides an indication of the performance of the droop mitigation scheme.

The circuit may further comprise a clock circuit configured to: use the droop mitigation scheme to generate the clock output signal, wherein the droop mitigation scheme may comprise adjusting the clock output signal in response to detection of a droop event.

The circuit may further comprise a droop detector configured to detect droop in a monitored voltage supply.

The circuit may further comprise a droop mitigation state machine configured to provide a clock selection signal to the clock circuit, in response to detection of droop in the monitored voltage supply by the droop detector.

The circuit may further comprise a delay monitor configured to generate the output, where the delay monitor may comprise at least one delay line and an encoder.

In a further approach there is provided a system comprising: the above circuitry, implemented in at least one packaged chip; at least one system component; and a board, wherein the at least one packaged chip and the at least one system component are assembled on the board.

In a further approach there is provided a chip-containing product comprising the above system assembled on a further board with at least one other product component.

In a further approach there is provided a non-transitory computer-readable medium to store computer-readable code for fabrication of the above circuitry.

The method, circuit according to the present technology may thus be used in evaluating the performance of a droop mitigation scheme, and that method may be realised in the form of a non-transitory computer readable medium comprising a structure of data and imperatives operable to cause a device to construct a set of electronic logic components which, when embedded in an electronic device and activated thereon, cause the electronic device to perform the steps of the method of the present technology as described hereinabove.

As will be clear to one of skill in the art, a hybrid approach may also be taken, in which hardware logic, firmware and/or software may be used in any combination to implement the present technology.

### BRIEF DESCRIPTION OF THE DRAWINGS

Implementations of the disclosed technology will now be described, by way of example only, with reference to the accompanying drawings, in which:

FIG. 1 shows a simplified view of a method of evaluating the performance of a droop mitigation scheme;

FIG. 2 shows a simplified view of a droop mitigation scheme;

FIG. 3 shows a simplified representation of a timing diagram;

FIG. 4 shows a simplified representation of a further timing diagram;

FIG. 5 shows a simplified representation of one possible apparatus, system or arrangement of electronic circuit components operable to be used in a method of evaluating the performance of a droop mitigation scheme;

FIG. 6 shows a simplified representation of a delay monitor; and

FIG. 7 shows a system and a chip-containing product.

### DETAILED DESCRIPTION

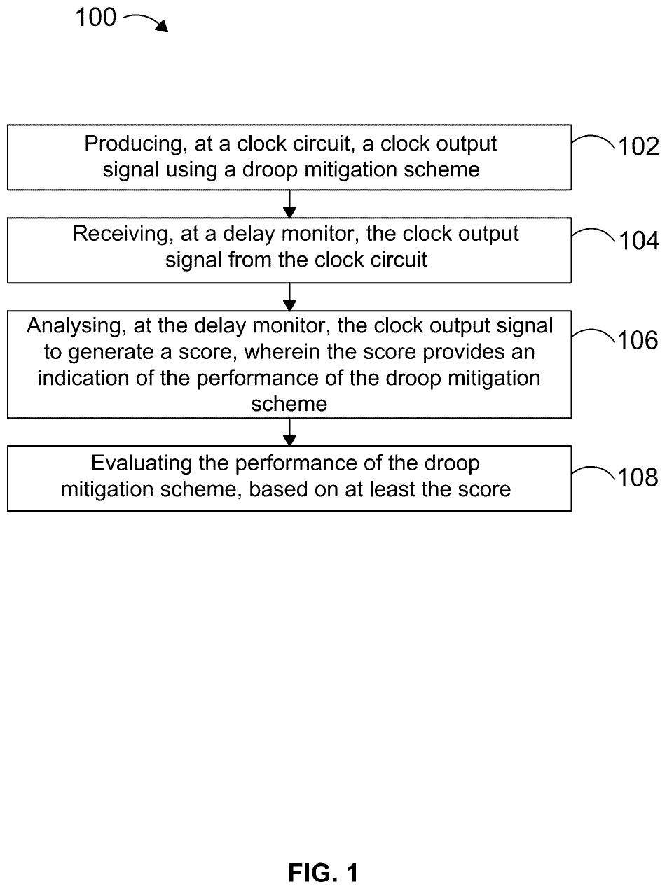

Turning now to FIG. 1, there is shown a very simplified view of a method 100 according to implementations of the presently described technology. The method 100 comprises the following steps: producing, at a clock circuit, a clock output signal, wherein a droop mitigation scheme has been used to generate the clock signal (step 102); receiving, at a delay monitor, the clock output signal from the clock circuit (step 104); and analysing, at the delay monitor, the clock output signal to generate an output (e.g. having an output value or score), wherein the output provides an indication of the performance of the droop mitigation scheme (step 106). Optionally, the method 100 further comprises: evaluating the performance of the droop mitigation scheme, based on at least the output (step 108).

The method 100 is a method of evaluating the performance of a droop mitigation scheme. “Droop” refers to the loss or reduction of supply voltage across a processor/chip resulting from fluctuations in workload. Droop is typically caused by sudden activity changes for a processor/chip or when the current load changes at or near the resonance frequency of the power delivery network impedance. By “droop mitigation scheme” it is meant a scheme or method that can be used to mitigate against the negative effects of voltage droop i.e. a scheme or method to reduce or eliminate the impact on process/chip functionality due to loss of supply voltage across a processor/chip during a droop event.

At 102, the method 100 comprises producing, at a clock circuit, a clock output signal. As will be explained in further detail below, producing a clock output signal involves receiving a plurality of clock input signals and selecting one of the clock input signals or none of the clock input signals as the clock output signal. In the present example a clock output signal is produced by the clock circuit in accordance with a droop mitigation scheme. The droop mitigation scheme mitigates against the negative effects of voltage droop. In this sense, the output of the clock circuit is a mitigated clock signal.

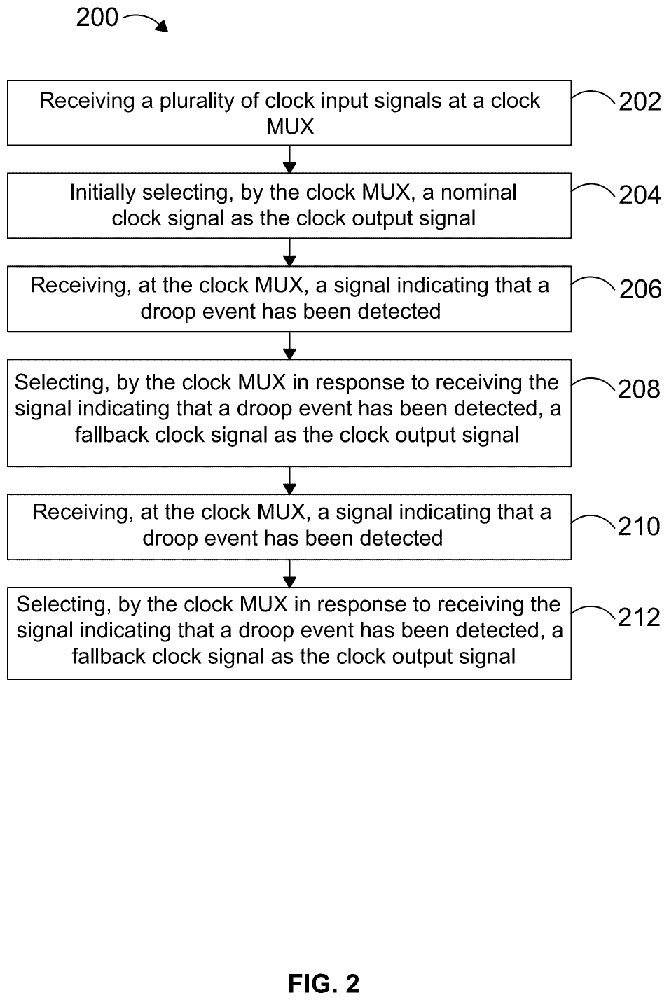

In the present example, a droop mitigation scheme is used to generate the clock output signal. The droop mitigation scheme relies on selecting an initial clock signal having a particular frequency (e.g. 3.5 GHz) and voltage (e.g. 0.95 V) as the clock output signal, and adjusting the frequency in response to detection of a droop event. An illustrative example droop mitigation scheme is explained in further detail below in relation to FIG. 2.

We now turn briefly to FIG. 2 which shows an example droop mitigation scheme 200. The example droop mitigation scheme 200 comprises the following steps: receiving a plurality of clock input signals at a clock mux (step 202); initially selecting, by the clock mux, a nominal clock signal as the clock output signal (step 204); receiving, at the clock mux, a signal indicating that a droop event has been detected (step 206); and selecting, by the clock mux in response to receiving the signal indicating that a droop event has been detected, a fallback clock signal as the clock output signal (step 208). Optionally, the droop mitigation scheme 200 further comprises: receiving, at the clock mux, a signal indicating that the droop event has ended or is no longer detected (step 210); and selecting, by the clock mux in response to receiving the signal indicating that the droop event has ended or is no longer detected, the nominal clock signal as the clock output signal (step 212).

At 202, a plurality of clock input signals are received at a clock mux. The plurality of clock input signals comprise a nominal clock signal and a fallback clock signal. The nominal clock signal and the fallback clock signal have different frequencies. Since the effects of droop are more severe at higher clock frequencies, the fallback clock signal, which is to be selected by the clock mux during droop events, typically has a lower frequency than the nominal clock signal. In an example, the nominal clock signal has a frequency of 3.5 GHz and the fallback clock signal has a frequency of 3.2 GHz, for example.

At 204, the nominal clock signal is initially selected for use as the clock output signal by the clock mux. In other words, by default the clock output signal is the nominal clock signal. As is explained in further detail below, the clock mux comprises a clock selection input which receives a signal from a droop mitigation state machine.

During the method 200, a droop detector is used to monitor the voltage of a sub-system for a voltage droop event. The occurrence of the voltage droop event may be obtained, for example, via an interface at the droop detector.

On detection of a droop event by the droop detector, a trigger signal is output from the droop detector, and this trigger signal is input to the droop mitigation state machine.

At 206, the clock mux receives a signal indicating that a droop event has been detected and that mitigation action should be taken. The signal indicating that a droop event has been detected and that mitigation action should be taken is received at the clock selection input of the clock mux from the droop mitigation state machine, which in turn receives a trigger signal output from the droop detector.

At 208, in response to receiving the signal indicating that a droop event has been detected and that mitigation action should be taken, the clock mux selects the fallback clock signal as the clock output signal. In other words, the output from the droop mitigation state machine, which is provided to the clock selection input of the clock mux, causes the clock mux to switch its output from the nominal clock signal (having a first frequency) to the fallback clock signal (having a second frequency). As will be appreciated, there will be at least some switching time while the output of the clock mux is switched between the nominal and fallback clock signals. During this switching time, no output signal is provided by the clock output signal.

At 210, the clock mux receives a signal indicating that the droop event has ended/is no longer detected and that mitigation action should no longer be taken. The signal output by the droop mitigation state machine, which is provided as the clock selection input at the clock mux, may change when the droop detector no longer detects droop i.e. when the trigger output from the droop detector switches from high to low. There may be a programmable delay between when the droop mitigation state machine no longer receives the trigger input from the droop detector and when the output of the droop mitigation state machine switches. For example, the delay may be 6 clock cycles of the fallback clock signal, although this is only an example and the delay may be any number of clock cycles.

At 212, in response to receiving the signal indicating that the droop event has ended or is no longer detected, the clock mux selects the nominal clock signal as the clock output signal. Again, as will be appreciated, there will be at least some switching time during which the output of the clock mux is switched between the fallback and nominal clock signals. During this switching time, no output signal is provided by the clock output signal.

Since the effects of droop are more severe at higher clock frequencies, the example droop mitigation scheme 200 reduces droop by using a reduced clock frequency for some or all of the duration of a droop event.

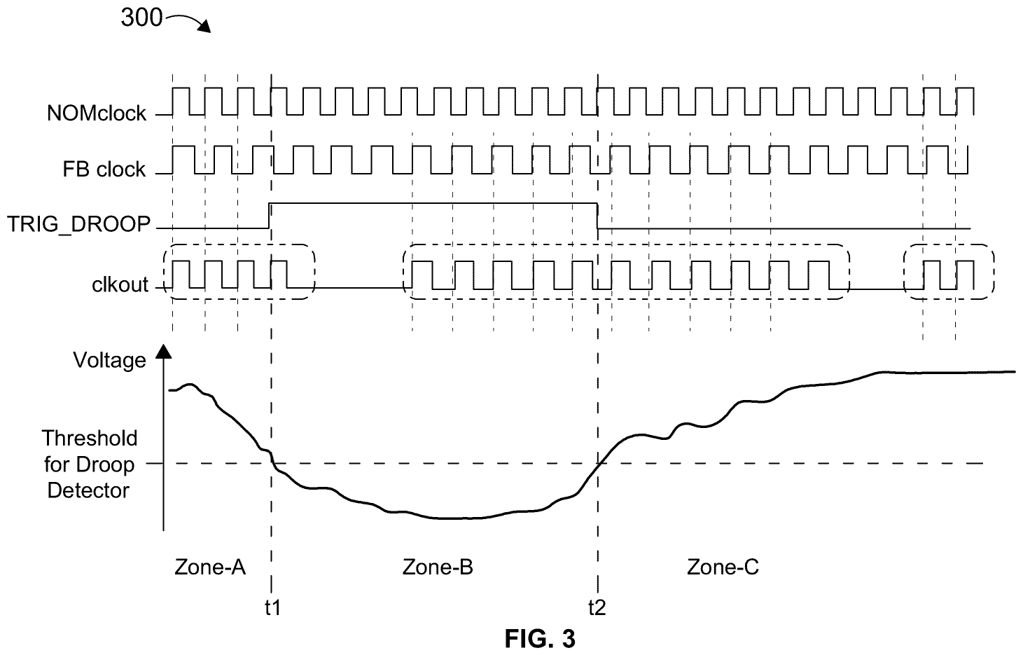

FIG. 3 is a timing diagram which illustrates the effect of the example droop mitigation scheme 200 during a droop event.

Initially, in Zone A, the voltage of the monitored sub-system is above a threshold set for the droop detector, and therefore no droop event is detected. Initially, in Zone A, the output of the droop detector (TRIG_DROOP) is low and the nominal clock signal (NOMclock) is used as the clock output signal (clkout).

At time t1, i.e. at the start of Zone B, the voltage falls below the threshold set for the droop detector. Therefore a droop event is detected in Zone B. On detection of the droop event, the output of the droop detector (TRIG_DROOP) switches from low to high. As a result of the high output of the droop detector, the droop mitigation state machine causes the clock mux to select (after a delay) the fallback clock signal (FBclock) as the clock output signal (clkout).

At time t2, i.e. at the start of Zone C, the voltage rises above the threshold set for the droop detector. Therefore the droop event is no longer detected in Zone C. On detection of the end of the droop event, the output of the droop detector (TRIG_DROOP) switches from high to low. As a result of the low output of the droop detector, the droop mitigation state machine causes the clock mux to select (after a delay) the nominal clock signal (NOMclock) as the clock output signal (clkout). In this example, the droop mitigation state machine uses a programmable delay between when the droop mitigation state machine no longer receives the high trigger input from the droop detector and when the output of the droop mitigation state machine switches from high to low. In this example, the delay is 6 clock cycles of the fallback clock signal, although this is only an example and the delay may be any number of clock cycles may be used.

As will be appreciated, other droop mitigation schemes are possible. For example, a further droop mitigation scheme is “stop the clock” in which the clock output signal is stopped (rather than switching to a fallback clock) in response to the detection of a voltage droop event. A yet further droop mitigation scheme is “ignore the droop” in which no action is taken in response to the detection of a voltage droop event (i.e. the nominal clock is used throughout the duration of a droop event). The method 100 provides a way to suitably characterise different droop mitigation schemes, to see which scheme is most effective in mitigating droop for a particular processor/chip design.

Returning to FIG. 1, at 104 the method 100 comprises receiving, at a delay monitor, the mitigated clock output signal from the clock circuit (i.e. the output of the clock mux).

At 106 the method 100 comprises analysing, at the delay monitor, the clock output signal to generate an output. The delay monitor is configured to generate an output (e.g. an output value or score) which is indicative of the performance of the droop mitigation scheme. The output corresponds to a count of a number of fine gate stages traversed in a delay line during a predetermined number of clock cycles, which could, for example, be one clock cycle, although this is only an example and the output could correspond to a count of a number of fine gate stages traversed in a delay line during any predetermined number of clock cycles. The output is indicative of the voltage of the sub-system.

At 108, the method 100 comprises evaluating the performance of the droop mitigation scheme, based on at least the output. The performance of the droop mitigation scheme can be evaluated by monitoring and recording changes of the output over a period of time, in particular before, during and after droop events, and comparing the output with one or more thresholds.

Evaluation circuitry can be used to save the outputs from the delay monitor in memory. For example, the output can be saved every n clock cycles of the nominal clock, where n=1, 2, 3, etc. As an alternate, the output statistics in terms of minimum and maximum value of output score over a period of time. Monitoring for changes of the output over a period of time, in particular before, during and after droop events, provides an indication of how well the droop mitigation scheme used to generate the mitigated clock signal has performed. The evaluation circuitry can be used to compare the output from the delay monitor with a plurality of thresholds.

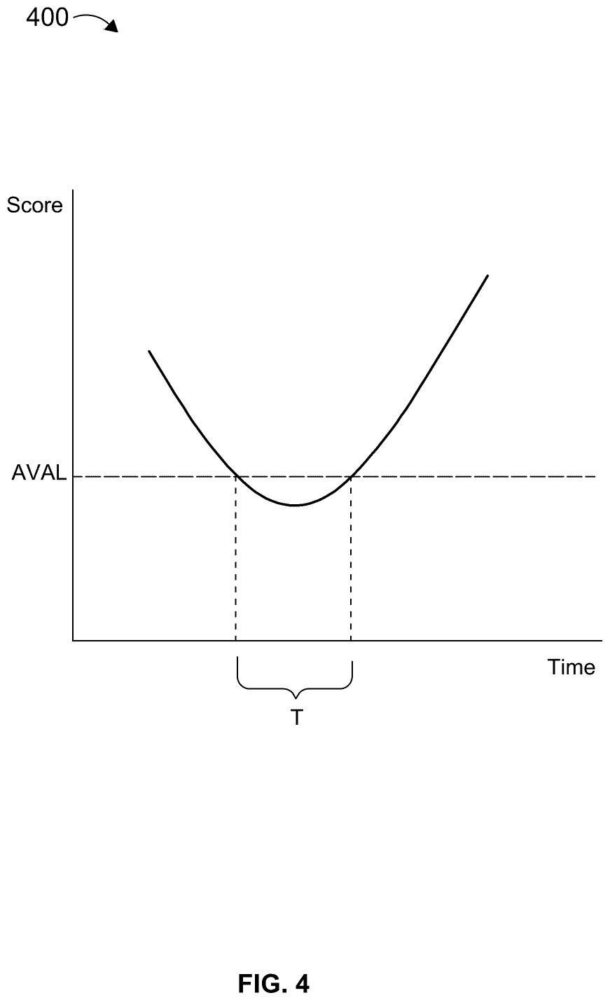

FIG. 4 shows an example of the changes of the output over a period of time. Initially, the output is above a threshold AVAL and therefore the output is in a “Safe Zone”. When the droop mitigation scheme is working effectively, the output remains above the first threshold and in the Safe Zone before, during and after the droop event.

In the example of FIG. 4, during time T the output falls below the threshold AVAL. The output falling below the threshold indicates that the droop mitigation scheme is not working as effectively, and that the circuit is suffering from the effects of droop. In response to the output falling below the threshold, the evaluation circuitry may provide a droop performance indication signal(s) signal to indicate that the droop mitigation scheme should be adjusted and/or replaced with an alternative droop mitigation scheme. Parameters of the droop mitigation scheme may be automatically adjusted. For example, the frequency of a fallback clock signal may be automatically reduced by the evaluation circuitry in response to determining that the output has fallen below the threshold AVAL.

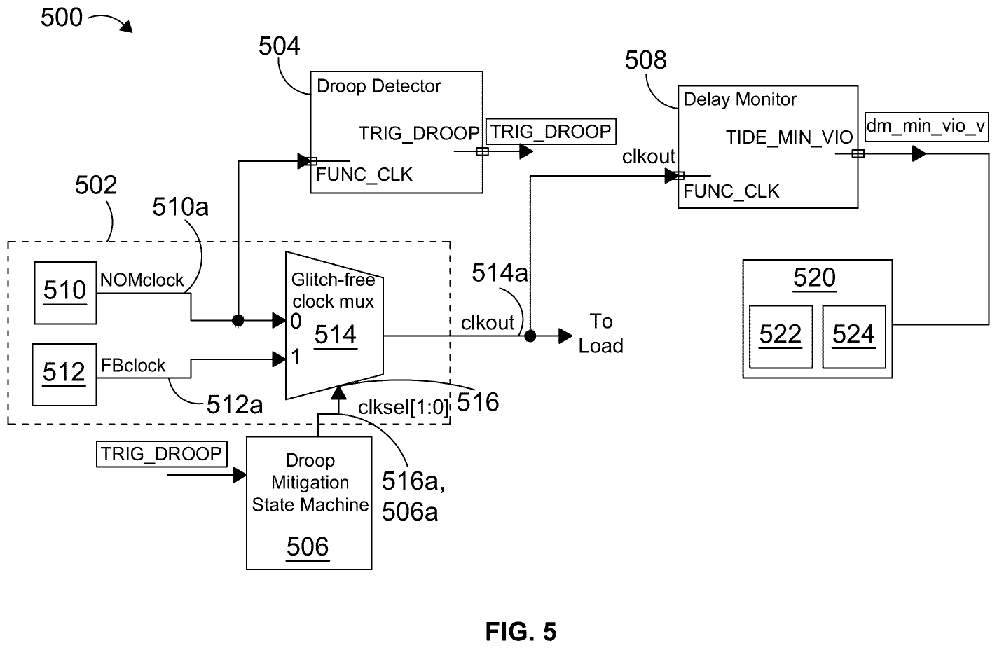

Turning now to FIG. 5, there is shown a simplified representation of one possible apparatus, system or arrangement of electronic circuit components forming a circuit 500 operable according to an implementation of the presently described technology. In particular, the circuit 500 can be used to perform the methods 100 and 200.

The circuit 500 comprises a clock circuit 502, a droop detector 504, a droop mitigation state machine 506, a delay monitor 508 and evaluation circuitry 520. The circuit 500 may form part of a Processing Unit such as a CPU or a GPU. The circuit 500 may be used to provide a clock signal to the other components of the CPU or GPU.

The clock circuit 502 comprises a plurality of clock sources 510/512 and a clock mux 514. Each clock source 510/512 produces a clock signal 510a/512a having a particular frequency and a voltage. The clock sources 510/512 include a nominal clock source 510 and a fallback clock source 512. The nominal clock signal 510a (NOMclock) and the fallback clock signal 512a (FBclock) have different frequencies, as described above.

Since the effects of droop are more severe at higher clock frequencies, the fallback clock signal 512a, which is to be selected by the clock mux 514 during droop events, typically has a lower frequency than the nominal clock signal 510a. In an example, the nominal clock signal has a frequency of 3.5 GHz and the fallback clock signal has a frequency of 3.2 GHz.

In use, the clock mux 514 receives each clock signal 510a/512a as input and outputs a clock output signal 514a (clkout). The selection of the clock output signal 514a is controlled by a clock selection input 516. The clock selection input 516 is configured to receive a clock selection signal 516a from a droop mitigation state machine. When the signal at the clock selection input 516 (i.e. the output from the droop mitigation state machine) is 2′b01, the clock output signal 514a (clkout) will be the nominal clock signal 510a (NOMclock). When the signal at the clock selection input 516 (i.e. the output from the droop mitigation state machine) is 0′b10, the clock output signal 514a (clkout) will be the fallback clock signal 512a (FBclock). When the signal at the clock selection input 516 (i.e. the output from the droop mitigation state machine) is 2′b00, no clock is selected for the clock output signal 514a (clkout) i.e. the clkout signal is stopped such that the propagation of clock signals from the clock circuit 502 is stopped.

The default output 506a of the droop mitigation state machine 506 is 2′b01 and therefore by default the clock output signal 514a (clkout) will be the nominal clock signal 510a (NOMclock). On receiving an indication from the droop detector 504 that a droop event has been detected, the output of the droop mitigation state machine 506 switches to 2′b10 and the clock output signal 514a (clkout) will be the fallback clock signal 512a (FBclock). While switching between the nominal clock signal 510a and the fallback clock signal 512a, no output signal is provided from the clock circuit.

A programmable delay may be used by the droop mitigation state machine 506 between when the droop mitigation state machine no longer receives the high trigger input from the droop detector and when the output of the droop mitigation state machine switches from high to low. For example, the delay may be 6 clock cycles of the fallback clock signal.

The droop detector 504 is configured to monitor (i.e. continuously monitor) the monitored voltage (e.g. of a sub-system) for a voltage droop event. The droop detector 504 compares its output (for example, score) with one or more thresholds. The droop detector 504 identifies a droop event when the score of the monitored voltage falls below a threshold. On detection of a droop event by the droop detector 504, a trigger signal (TRIG_DROOP) is output from the droop detector 504 and input to the droop mitigation state machine 506. TRIG_DROOP is synchronised with the rising edge of the nominal clock signal 510a.

The droop mitigation state machine 506 is configured to control the mitigation action taken by the clock circuit 502 when the droop detector 504 detects a droop event. The droop mitigation state machine 506 is configured to receive the trigger signal (TRIG_DROOP) from the output of the droop detector 504 and to provide a clock selection input 516 to the clock mux 514.

The output of the droop mitigation state machine 506 can be 2′b01, 2′b10 or 2′b00. When the output from the droop mitigation state machine 506 is 2′b01, the nominal clock signal 510a is selected as the clock output signal 514a. When the output from the droop mitigation state machine 506 is 2′b10, the fallback clock signal 512a is selected as the clock output signal 514a. When the output from the droop mitigation state machine 506 is 2′b00, no clock is selected for the clock output signal 514a such that the clkout signal is stopped and the propagation of clock signals from the clock circuit 502 is stopped. The default output 506a of the droop mitigation state machine 506 is 2′b01 and therefore by default the clock output signal 514a (clkout) will be the nominal clock signal 510a (NOMclock).

In the example droop mitigation scheme 200 outlined above in relation to FIG. 2, the output of the droop mitigation state machine 506 switches from 2′b01 to 2′b10 when a droop event is detected (i.e. when TRIG_DROOP switches from low to high), but other schemes are possible. For example, in a “stop the clock” droop mitigation scheme, the output of the droop mitigation state machine 506 switches from 2′b01 to 2′b00 when a droop event is detected. In an “ignore the droop” droop mitigation scheme, the output of the droop mitigation state machine 506 is not changed from 2′b01 when a droop event is detected.

The droop mitigation state machine 506 may provide a programmable switching delay. For example, when TRIG_DROOP switches from high to low, the output of the droop mitigation state machine 506 may not switch immediately from e.g. 2′b01 to 2′b10. Instead, the droop mitigation state machine 506 may switch its output after a count down of e.g. 6 clock cycles of the fallback clock signal. If TRIG_DROOP switches back to high during the delay, the count down may be reset.

The delay monitor 508 is configured to receive the mitigated clock output signal from the clock circuit 502 (i.e. the output 514a of the clock mux 514) and analyse the clock output signal 514a to generate a output (dm_min_vio_v). The output is indicative of the performance of the droop mitigation scheme used to generate the clock output signal 514a. The output corresponds to a count of a number of fine gate stages traversed in a delay line during a predetermined number of clock cycles.

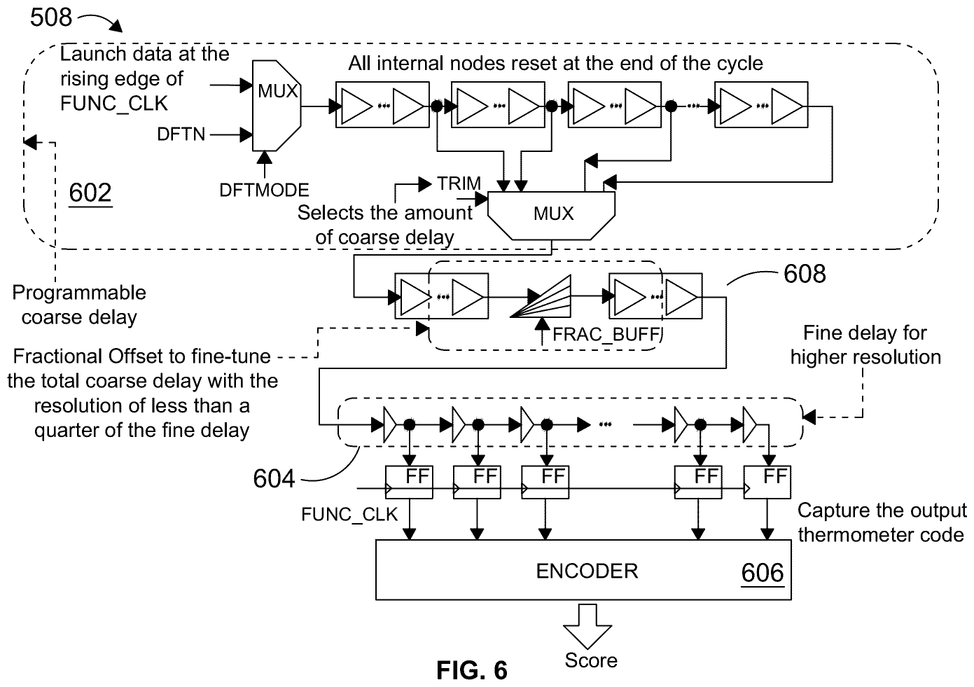

An example delay monitor 508 is shown in detail in FIG. 6. The delay monitor 508 comprises a coarse delay line 602, a fine delay line 604 and an encoder 606. The delay monitor optionally comprises a fractional offset 608 between the coarse delay and the fine delay.

The output is provided by the output of the encoder. The output corresponds to a count of the number of fine gate stages traversed in the fine delay line 604 during a predetermined number of clock cycles. The output may be measured every output clock cycle of the clock circuit 502 and averaged over a predetermined number of clock cycles for analysis.

The evaluation circuitry 520 comprises a memory 522 and processing circuitry 524. The memory 522 can be used to store the outputs from the delay monitor 508. For example, the memory 522 can store the time evolution of the output value or score (or average score every 1000 clock cycles, for example). In another example, the memory 522 can store the maximum and the minimum value of the output over a period of time. The memory 522 can also be used to store one or more thresholds against which the outputs are compared to evaluate performance of the droop mitigation scheme. For example, the memory 522 can be used to store the threshold AVAL. The processing circuitry 524 can be used to provide a droop performance indication signal(s) to indicate that the droop mitigation scheme should be adjusted and/or replaced with an alternative droop mitigation scheme, and may be configured to adjust or reduce the frequency of the fallback clock signal 512a in response to determining that the output from the delay monitor 508 has fallen below the threshold AVAL.

As will be appreciated by one skilled in the art, the present technology may be embodied as a method, a circuit or a computer readable medium comprising data and imperatives to cause construction of a circuit. Accordingly, the present techniques may take the form of an entirely hardware embodiment, an entirely software embodiment, or an embodiment combining software and hardware. Where the word “component” is used, it will be understood by one of ordinary skill in the art to refer to any portion of any of the above embodiments.

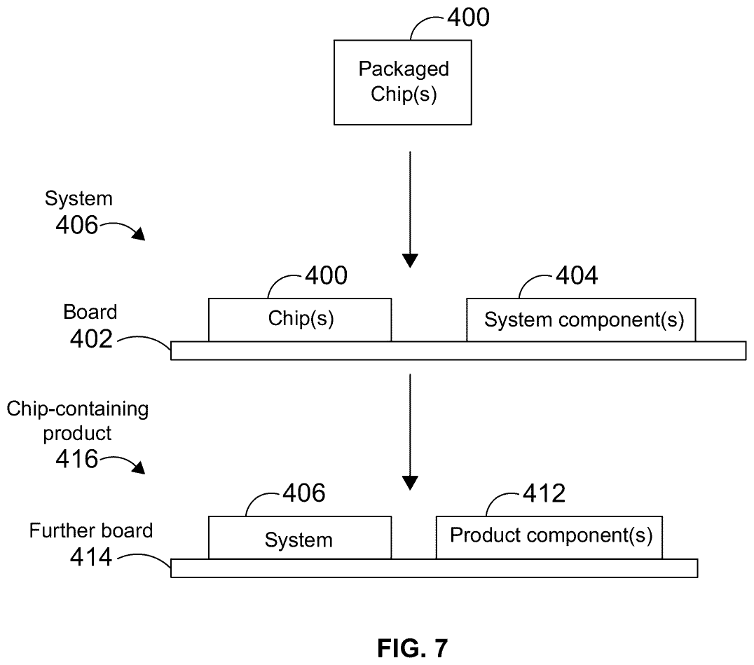

As shown in FIG. 7, one or more packaged chips 400, with the circuitry described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g. made of metal, plastic, glass or ceramic) containing the semiconductor devices implementing the circuitry described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g. using an interposer, or by using three-dimensional integration to provide a multi-layer chip product comprising two or more vertically stacked integrated circuit layers).

In some examples, a collection of chiplets (i.e. small modular chips with particular functionality) may itself be referred to as a chip. A chiplet may be packaged individually in a semiconductor package and/or together with other chiplets into a multi-chiplet semiconductor package (e.g. using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g. plastic, glass, ceramic, or a flexible substrate material such as paper, plastic or textile material. The at least one system component 404 comprise one or more external components which are not part of the one or more packaged chip(s) 400. For example, the at least one system component 404 could include, for example, any one or more of the following: another packaged chip (e.g. provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g. a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

As will be appreciated by one skilled in the art, the present technology may be embodied as a method, a circuit or a computer readable medium comprising data and imperatives to cause construction of a circuit. Accordingly, the present techniques may take the form of an entirely hardware embodiment, an entirely software embodiment, or an embodiment combining software and hardware. Where the word “component” is used, it will be understood by one of ordinary skill in the art to refer to any portion of any of the above embodiments.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the present techniques. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the present techniques. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

In the present application, lists of features preceded with the phrase “at least one of” mean that any one or more of those features can be provided either individually or in combination. For example, “at least one of: [A], [B] and [C]” encompasses any of the following options: A alone (without B or C), B alone (without A or C), C alone (without A or B), A and B in combination (without C), A and C in combination (without B), B and C in combination (without A), or A, B and C in combination.

Although illustrative embodiments of the present techniques have been described in detail herein with reference to the accompanying drawings, it is to be understood that the present techniques are not limited to those precise embodiments, and that various changes and modifications can be effected therein by one skilled in the art without departing from the scope of the present techniques as defined by the appended claims.

1. A method of evaluating the performance of a droop mitigation scheme, wherein the method is carried out at a circuit, the method comprising:
receiving a clock output signal, wherein the droop mitigation scheme has been used to generate the clock output signal; and
analysing the clock output signal to generate an output, wherein the output provides an indication of the performance of the droop mitigation scheme.

2. The method of claim 1, further comprising:
using the droop mitigation scheme to generate the clock output signal,
wherein the droop mitigation scheme comprises adjusting the frequency of the clock output signal in response to a droop event.

3. The method of claim 2, wherein using a droop mitigation scheme to generate the clock output signal comprises:
receiving a plurality of clock input signals, the plurality of clock input signals comprising a nominal clock signal and a fallback clock signal;
providing, for at least a first time period, the nominal clock signal as the clock output signal; and
providing, for at least a second time period, the fallback clock signal or no signal as the clock output signal.

4. The method of claim 3, further comprising:
monitoring the voltage for a voltage droop event.

5. The method of claim 4, wherein using a droop mitigation scheme to generate a clock output signal further comprises:
initially providing the nominal clock signal as the clock output signal;
responsive to detecting a voltage droop event, providing the fallback clock signal or no signal as the clock output signal.

6. The method of claim 3, wherein the nominal clock signal and the fallback clock signal have different frequencies.

7. The method of claim 1, further comprising:
evaluating the performance of the droop mitigation scheme, based on at least the output.

8. The method of claim 7, wherein evaluating, based on at least the output, the performance of the droop mitigation scheme comprises:
comparing an output value of the output with one or more thresholds.

9. The method of claim 8, wherein evaluating, based on the output, the performance of the droop mitigation scheme comprises:
in response to determining that the output is below a threshold, providing a droop performance indication signal or adjusting the droop mitigation scheme.

10. The method of claim 1, wherein the circuit comprises a clock circuit comprising a plurality of clock sources and a clock mux, wherein the plurality of clock sources comprises a nominal clock source and a fallback clock source.

11. The method of claim 10, wherein the circuit comprises a droop detector configured to detect droop in the nominal clock signal.

12. The method of claim 11, wherein the circuit comprises a droop mitigation state machine configured to provide a clock selection signal to the clock circuit, in response to detection of droop in the nominal clock signal by the droop detector.

13. The method of claim 1, wherein the circuit comprises a delay monitor configured to generate the output, the delay monitor comprising at least one delay line and an encoder.

14. A circuit for evaluating the performance of a droop mitigation scheme, the circuit comprising a delay monitor configured to:
receive a clock output signal, wherein the droop mitigation scheme has been used to generate the clock output signal;
analyse the clock output signal to generate an output, wherein the output provides an indication of the performance of the droop mitigation scheme.

15. The circuit of claim 14, further comprising a clock circuit configured to:
use the droop mitigation scheme to generate the clock output signal,
wherein the droop mitigation scheme comprises adjusting the clock output signal in response to detection of a droop event.

16. The circuit of claim 15, further comprising a droop detector configured to detect droop in a monitored voltage supply.

17. The circuit of claim 16, further comprising a droop mitigation state machine configured to provide a clock selection signal to the clock circuit, in response to detection of droop in the monitored voltage supply by the droop detector.

18. A system comprising:
the circuitry of claim 15, implemented in at least one packaged chip; at least one system component; and
a board,
wherein the at least one packaged chip and the at least one system component are assembled on the board.

19. A chip-containing product comprising the system of claim 18 assembled on a further board with at least one other product component.

20. A non-transitory computer-readable medium to store computer-readable code for fabrication of the circuitry of claim 15.
